(19) United States
(12) Patent Application Publication
(10) Pub. No.: US 2009/0155450 A1
(43) Pub. Date: Jun. 18, 2009

(54) Method for manufacturing a stable freestanding pure water film

(75) Inventors: Jung Ho Je, Pohang-si (KR); Byung Mook Weon, Pohang-si (KR)

Correspondence Address: HARNESS, DICKEY & PIERCE, P.L.C., P.O. BOX 828, BLOOMFIELD HILLS, MI, 48303, US

(73) Assignee: POSTECH ACADEMY-INDUSTRY FOUNDATION, Pohang-si (KR)

(21) Appl. No.: 12/009,153

(22) Filed: Jan. 16, 2008

(30) Foreign Application Priority Data
Dec. 14, 2007 (KR) 10-2007-0130891

(51) Int. Cl. C23C 14/28

(52) U.S. Cl. 427/8; 427/595

(57) ABSTRACT

The present invention relates to a method for manufacturing a stable freestanding pure water film. More specifically, the invention relates to a method for manufacturing a stable freestanding pure water film by X-ray bombardment of a small pure water volume in a capillary tube, the X-ray bombardment evaporating the pure water volume to be a pure water thin film and at the same time charging the surface of the pure water thin film to be stabilized electrically.

### BACKGROUND OF THE INVENTION

1. Field of the Invention

The present invention relates to a method for manufacturing a stable freestanding pure water film. More specifically, the invention relates to a method for manufacturing a stable freestanding pure water film by X-ray bombardment of a small pure water volume in a capillary tube, the X-ray bombardment evaporating the pure water volume to be a pure water thin film and at the same time charging the surface of the pure water thin film to be stabilized electrically.

2. Background of the Related Art

In spite of the strong fundamental and applied interest in water microstructures, so far no technique was able to produce stable freestanding pure-water thin films.

The lifetime was limited to <1 ms—unsuitable for most applications—due to rapid rupture caused by the very low viscosity (˜1 mPa·s) and high surface tension (˜72 mN m⁻¹) of pure water in ambient conditions.

Water films have been stabilized by changing the hydrophilicity or the polarity with surfactants or electrolytes. These, however, can cause deviations from the intrinsic water properties.

### SUMMARY OF THE INVENTION

Therefore, the present invention has been made in view of the above problems, and it is an object of the present invention to provide a method for manufacturing a stable freestanding pure water film having a sufficently long life time to be suitable for most application without deviations from the intrinsic water properties.

To accomplish the object, according to one aspect of the present invention, there is provided a method for manufacturing a stable freestanding pure water film, the method comprising the steps of: (a) injecting pure water volume into capillary tube; and (b) bombarding the pure water volume with X-rays to obtain a stable freestanding pure water thin film, with both ends of the capillary tube sealed.

Preferably, the X-rays are in the photon energy range of 10-60 keV.

Preferably, the X-rays have the beam direction perpendicular to the capillary tube.

Preferably, the capillary tube are arranged horizentally.

Preferably, the capillary tube is a hydrophilic capillary tube.

Preferably, the step (a) is performed with a micropippete and a microneedle.

Preferably, the step (b) is monitored by phase-contrast microradiology.

Preferably, the pure water has the specific resistance of 18 MΩ.

Preferably, the pure water volume is 1 ul, the tube has radius of 680 um, the pure water volume is bombarded with the X-rays in the beam cross section of 0.5×0.4 mm² and the dose rate of 970 Gy/s.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a side image obtained by phase contrast microradiology of a stable freestanding pure-water film produced with the preferred embodiment of the present invention inside a horizontal capillary tube (radius R_{c}=680 μm).

FIG. 2 shows a scheme of the experimental procedure according to the preferred embodiment of the present invention. The X-ray bombardment occurs in the direction perpendicular to the capillary tube and reduces the distance between the two concave menisci—leading (red lines) to the formation of a thin flat film of radius r_{f}.

FIG. 3 is a sequence of phase contrast images revealing the evolution of the water film during X-ray bombardment according to the preferred embodiment of the present invention. The two concave menisci evolve towards a flat region and a freestanding thin film. As the X-ray bombardment continues, the diameter 2r_{f} of this flat region gradually increases as well as its thickness. After the end of the bombardment, the freestanding water film remains stable for more than 1 hour before rupturing, indicating that the X-rays play a stabilizing role in addition to causing water evaporation.

### DETAILED DESCRIPTION OF THE PREFERRED EMBODIMENT

The preferred embodiment of the invention will be hereafter described in detail, with reference to the accompanying drawings.

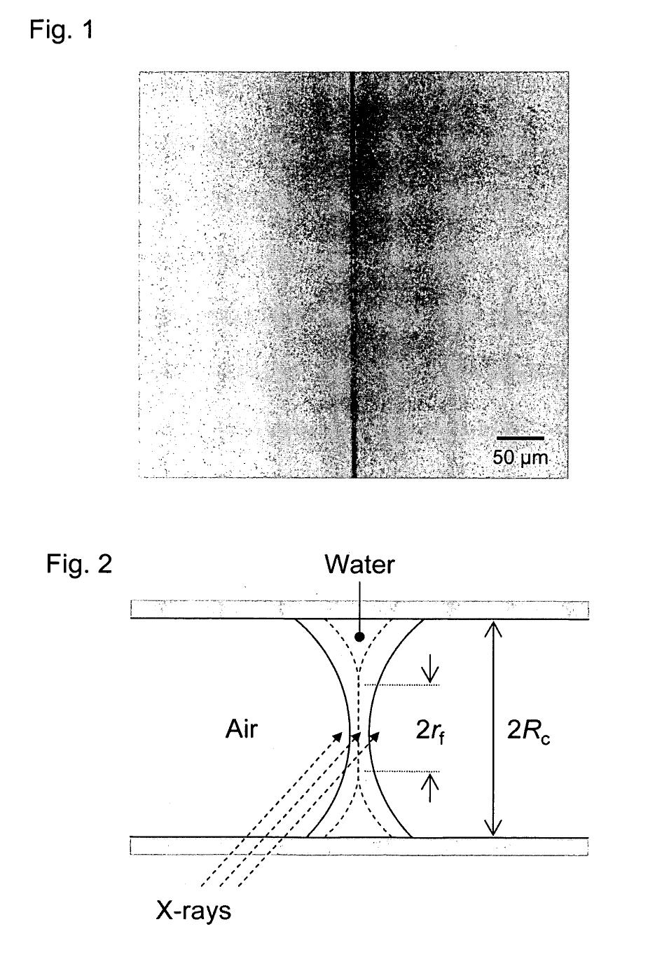

FIG. 1 is a side image obtained by phase contrast microradiology of a stable freestanding pure-water film produced with the preferred embodiment of the present invention inside a horizontal capillary tube (radius R_{c}=680 μm).

As shown in FIG. 1, we present here a new approach that produces large, micron-thick ultrapure-water films with excellent stability.

The approach is schematically illustrated by FIG. 2.

FIG. 2 shows a scheme of the experimental procedure according to the preferred embodiment of the present invention. The X-ray bombardment occurs in the direction perpendicular to the capillary tube and reduces the distance between the two concave menisci—leading (red lines) to the formation of a thin flat film of radius r_{f}.

Using a micropipette, we injected through a plastic microneedle (diameter <100 μm) ˜1 μL of 18 MΩ, Millipore ultrapure water in the middle of a horizontal hydrophilic Suprasil VitroCom capillary tube. The tube radius was R_{c}=290, 500 or 680 μm and the length ≈6 mm. Due to the hydrophilic character of the capillary tube, the injected water formed two concave menisci as shown in FIG. 2.

Both ends of the tube were then sealed and we bombarded the water volume with X-rays in the photon energy range 10-60 keV from the PLS synchrotron source (7B2 beamline) in Pohang, Korea. The X-ray beam direction (FIG. 2) was perpendicular to the tube and reached the side of the water volume. The beam cross section was 0.5×0.4 mm² and the dose rate was ≈970 Gy/s.

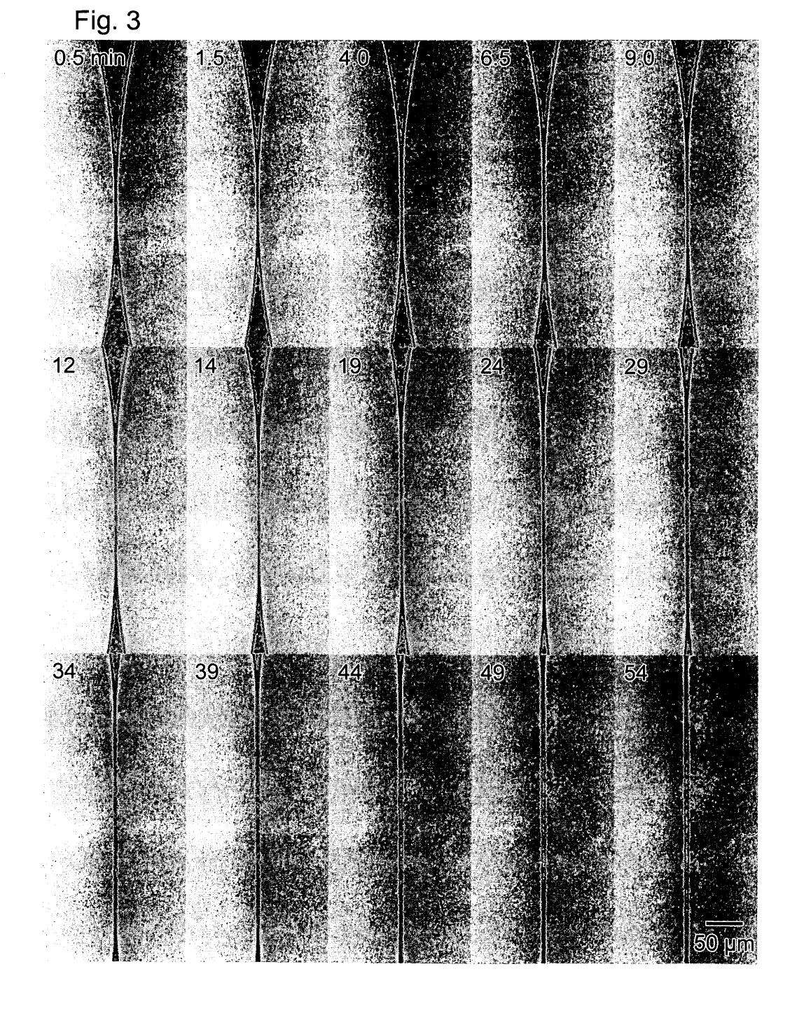

The process was carefully monitored (FIG. 3) by phase-contrast microradiology using the same X-ray beam as for the bombardment. The X-rays caused water evaporation at a rate ≈0.3 nL s⁻¹ for the R_{c}=680 μm tube. This progressively decreased the distance between the two menisci until a flat film was created—reminiscent of the liquid film between two adjoining gas-filled bubbles. The continuing X-ray bombardment then induced an increase of both the flat thin film radius and of its thickness, as seen in FIG. 3.

The film so created had a very long lifetime, indicating that the X-rays play a stabilizing role in addition to producing the film by evaporation. Quantitatively, the freestanding flat-film diameter 2r_{f} in the R_{c}=680 μm tube gradually evolved from ˜10 μm after 0.5 min irradiation to ˜0.4 mm after 54 min—whereas the thickness increased to a few microns.

After the bombardment ended, the 2r_{f}=0.4 mm film remained stable and unchanged in shape for more than 1 hour before rupture—even when mechanically tested by rotating the capillary tube. No stable film was obtained instead with the R_{c}=290 and 500 μm capillary tubes. Tests with vertical capillary tubes also failed to produce long-lived films.

What is the stabilization mechanism by the X-rays? The answer, we believe, is ionization and creation of electric charge on the water film surface.

Neither gravity nor heating seem to play a significant role in this context. Gravity is essentially negligible since the capillary radii are much smaller than the capillary length of water (2.8 mm). As to temperature, experiments with other systems under similar X-ray bombardment conditions only detected small (<1K) temperature increases. When the capillary tube temperature was artificially increased with a heater, the plugs that sealed its ends popped out.

Our interpretation in terms of electrostatic stabilization due to surface charging appears qualitatively and quantitatively plausible. The capillary pressure P_{c}=2γR_{c}/(R_{c}²−r_{f}²) (where γ is the water surface tension) would by itself continue to thin the film until it ruptures. The electrostatic repulsion due to surface charging can counter this thinning effect leading to the observed thickness increase and to long-term stability even for large r_{f}-values.

More precisely, the film thickness reaches equilibrium if P_{c} equals the disjoining pressure of the film. It is generally recognized that the disjoining pressure is primarily determined by the sum of the attractive van der Waals force and repulsive double-layer electrostatic force. Charging by the X-ray bombardment enhances this second factor allowing film stability even for large capillary pressures.

Note that P_{c}=2γR_{c}/(R_{c}²−r_{f}²) increases with r_{f}—so that avoiding rupture is more difficult for large-size films. Furthermore, P_{c} increases as R_{c} decreases; this explains why we could not obtain stable films for the R_{c}=290 and 500 μm capillary tubes. Even in those cases, however, the X-ray-induced charging effects were. noticeable: we analyzed the power-law time dependence of r_{f} and found a slow rupture dynamics.

Quantitatively, we can use the measured geometric parameters to evaluate P_{c}=2γR_{c}/(R_{c}²−r_{f}²). Assuming a constant γ, for the 2r_{f}=0.4 mm film in the R_{c}=680 μm tube we obtain P_{c}=320 Pa—which is in the range (100-1000 Pa) of the disjoining pressure values of electrolyte-stabilized water. This indicates that the X-rays act indeed as a surrogate for electrolytes in the film stabilization.

The dependence on the duration of the X-ray bombardment can be exploited to control the thickness and radius of the final films. Such stable freestanding microstructures of ultrapure water can lead to many interesting applications. We note cloud formation and colloidal crystallization plus many other cases in chemistry, physics, biology and materials science.

While the present invention has been described with reference to the particular illustrative embodiment, it is not to be restricted by the embodiment but only by the appended claims. It is to be appreciated that those skilled in the art can change or modify the embodiments without departing from the scope and spirit of the present invention.

What is claimed is:

1. A method for manufacturing a stable freestanding pure water film, the method comprising the steps of:
(a) injecting pure water volume into capillary tube; and
(b) bombarding the pure water volume with X-rays to obtain a stable freestanding pure water thin film, with both ends of the capillary tube sealed.

2. The method according to claim 1, wherein the X-rays are in the photon energy range of 10-60 keV.

3. The method according to claim 2, wherein the X-rays have the beam direction perpendicular to the capillary tube.

4. The method according to claim 1, wherein the capillary tube are arranged horizentally.

5. The method according to claim 1, wherein the capillary tube is a hydrophilic capillary tube.

6. The method according to claim 1, wherein the step (a) is performed with a micropippete and a microneedle.

7. The method according to claim 1, wherein the step (b) is monitored by phase-contrast microradiology.

8. The method according to claim 1, wherein the pure water has the specific resistance of 18 MΩ.

9. The method according to claim 8, wherein the pure water volume is 1 ul, the tube has radius of 680 um, the pure water volume is bombarded with the X-rays in the beam cross section of 0.5×0.4 mm² and the dose rate of 970 Gy/s.
